(19) United States
(12) Patent Application Publication
(10) Pub. No.: US 2025/0126778 A1
(43) Pub. Date: Apr. 17, 2025

(54) INTEGRATED CIRCUIT DEVICE

(71) Applicant: Samsung Electronics Co., Ltd., Suwon-si (KR)

(72) Inventors: Sangmin Lee, Suwon-si (KR); Yeonjin Hwang, Suwon-si (KR); Munjun Kim, Suwon-si (KR); Iksoo Kim, Suwon-si (KR); Junwon Lee, Suwon-si (KR); Younseok Choi, Suwon-si (KR)

(21) Appl. No.: 18/768,579

(22) Filed: Jul. 10, 2024

(30) Foreign Application Priority Data
Oct. 13, 2023 (KR) 10-2023-0137039

(51) Int. Cl. H10B 12/00

(52) U.S. Cl. CPC H10B 12/485; H10B 12/315; H10B 12/482

(57) ABSTRACT

An integrated circuit device and a method of manufacturing the same are provided. The integrated circuit device includes: a substrate having a plurality of active regions; a bit line extending on the substrate in a horizontal direction parallel to an upper surface of the substrate; a direct contact electrically connected to a first active region of the plurality of active regions and connected to the bit line; a contact plug electrically connected to a second active region of the plurality of active regions adjacent to the first active region; and an outer insulation spacer between the bit line and the contact plug and overlapping the bit line in a vertical direction perpendicular to the upper surface of the substrate. The outer insulation spacer includes a doped region doped with a metal element.

### CROSS-REFERENCE TO RELATED APPLICATION(S)

This application is based on and claims priority under 35 U.S.C. § 119 to Korean Patent Application No. 10-2023-0137039, filed on Oct. 13, 2023, in the Korean Intellectual Property Office, the disclosure of which is incorporated by reference herein in its entirety.

### BACKGROUND

The present inventive concept relates generally to an integrated circuit device, and more particularly, to an integrated circuit device including a conductive line and a landing pad above the conductive line.

Recently, due to rapid down-scaling of integrated circuit devices, the gap between each of a plurality of conductive lines in an integrated circuit device is narrowing, and thus the distance between the plurality of conductive lines and a landing pad above the plurality of conductive lines is gradually decreasing. As an insulation structure separating a plurality of conductive lines and a landing pad is consumed in a subsequent etching process, there is a need to develop technology to implement a structure capable of maintaining the reliability of the plurality of conductive lines.

### SUMMARY

The present inventive concept, as manifested in one or more embodiments thereof, provides an integrated circuit device with improved reliability by preventing excessive consumption of an insulation structure separating a plurality of conductive lines from a plurality of landing pads above the plurality of conductive lines during a subsequent etching process.

In addition, the technical goals to be achieved by the disclosure are not limited to the technical goals mentioned above, and other technical goals may be clearly understood by one of ordinary skill in the art from the following descriptions.

According to an aspect of the present inventive concept, there is provided an integrated circuit device including a substrate having a plurality of active regions, a bit line extending in a horizontal direction on the substrate parallel to an upper surface of the substrate, a direct contact connecting to a first active region selected from among the plurality of active regions and connected to the bit line, a contact plug connecting to a second active region adjacent to the first active region, and an outer insulation spacer extending between the bit line and the contact plug and overlapping the bit line in a vertical direction perpendicular to the upper surface of the substrate, wherein the outer insulation spacer includes a doped region doped with a metal element.

According to another aspect of the present inventive concept, there is provided an integrated circuit device including a substrate having a plurality of active regions, a bit line extending in a horizontal direction on the substrate, a direct contact connecting to a first active region selected from among the plurality of active regions and connected to the bit line, a contact plug connecting to a second active region adjacent to the first active region, a conductive landing pad extending in a vertical direction on the contact plug and electrically connected to the second active region through the contact plug, an outer insulation spacer extending between the bit line and the contact plug, overlapping the bit line in a vertical direction, and including a doped region, and an insulation capping film between the conductive landing pad and the outer insulation spacer.

According to another aspect of the present inventive concept, there is provided an integrated circuit device including a substrate having a plurality of active regions, a direct contact connecting to a first active region selected from among the plurality of active regions, a contact plug connecting to a second active region adjacent to the first active region in a first horizontal direction parallel to an upper surface of the substrate, a bit line extending longitudinally on the substrate in a second horizontal direction parallel to the upper surface of the substrate and intersecting the first horizontal direction and connecting to the direct contact, a conductive landing pad extending in a vertical direction perpendicular to the upper surface of the substrate on the contact plug and spaced apart from the bit line, an insulation capping pattern between the bit line and the conductive landing pad on the bit line, an inner insulation spacer extending along sidewalls of the direct contact and the bit line and covering (i.e., on or over) a top surface of the insulation capping pattern, an outer insulation spacer between the conductive landing pad and the inner insulation spacer, and an intermediate insulation spacer disposed between the inner insulation spacer and the outer insulation spacer, wherein an upper portion of the outer insulation spacer is doped with a metal element.

### BRIEF DESCRIPTION OF THE DRAWINGS

Embodiments of the present inventive concept will be more clearly understood from the following detailed description taken in conjunction with the accompanying drawings, wherein like reference numerals (when used) indicate corresponding elements throughout the several views, and in which:

FIG. 1 is a schematic layout (i.e., top plan view) diagram of an example integrated circuit device according to one or more embodiments;

FIG. 2A is a schematic cross-sectional view of the integrated circuit device shown in FIG. 1, taken along line A-A′ in FIG. 1;

FIG. 2B is a schematic cross-sectional view of the integrated circuit device shown in FIG. 1, taken along line B-B′ in FIG. 1;

FIG. 2C is an enlarged cross-sectional view of a region EX1 of FIG. 2A;

FIG. 3 is a schematic cross-sectional view of a region of an integrated circuit device according to other embodiments;

FIG. 4 is a schematic cross-sectional view of a region of an integrated circuit device according to other embodiments;

FIGS. 5A, 5B to 14A, 14B, 15A, 15B, 15C, 16A, 16B, 16C and 17A, 17B to 21A, 21B are schematic cross-sectional views depicting intermediate processes in an example method of manufacturing an integrated circuit device, according to embodiments,

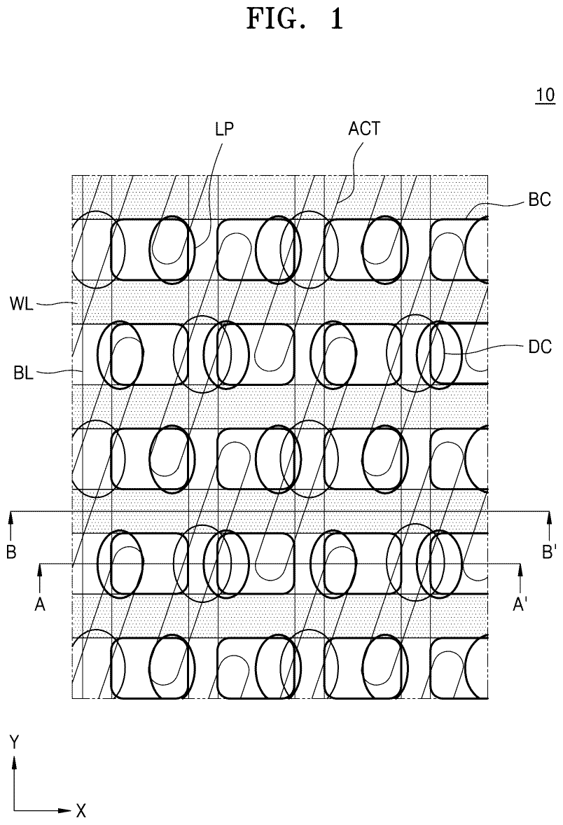

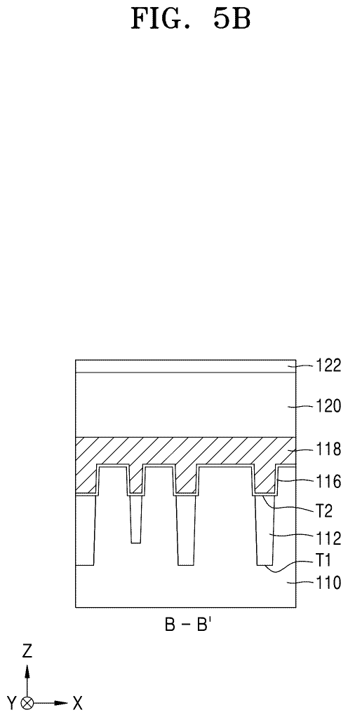

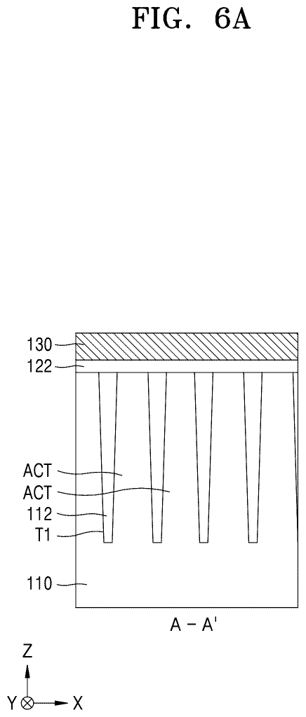

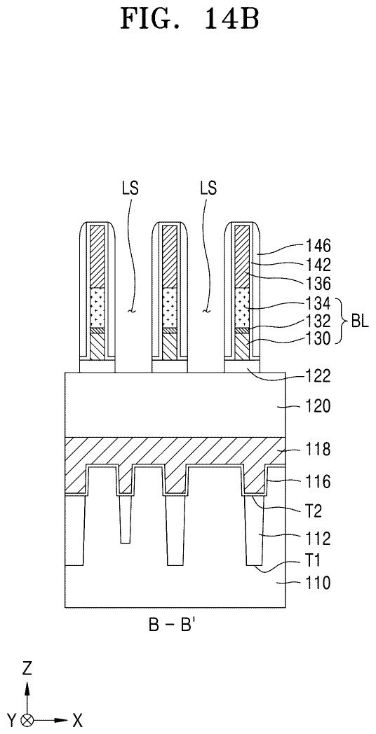

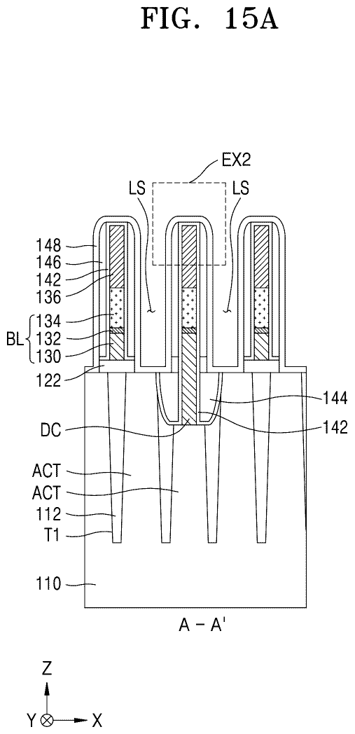

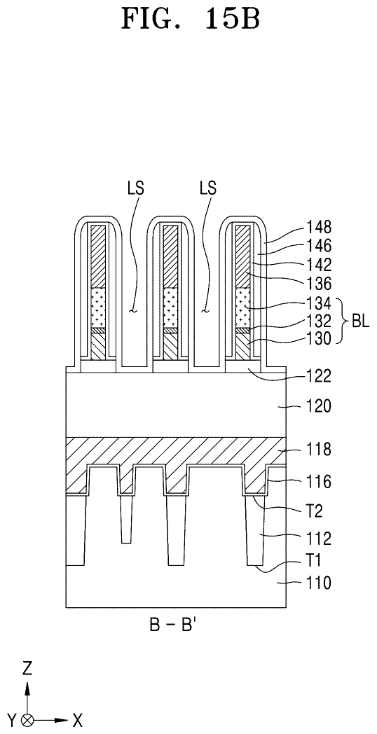

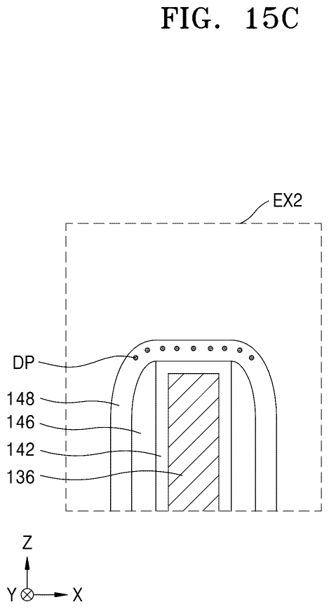

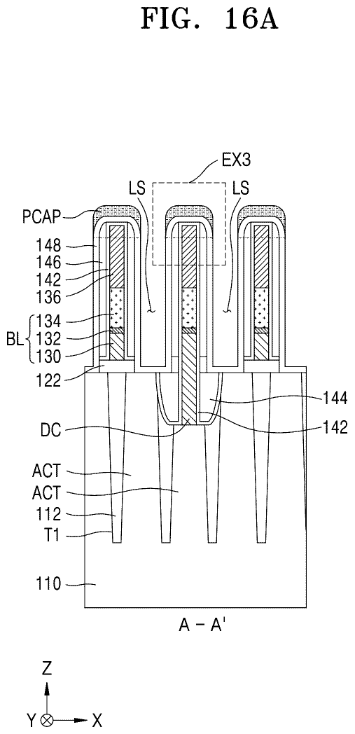

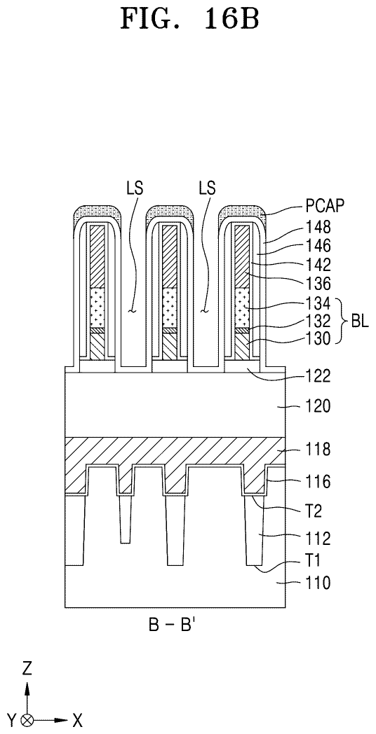

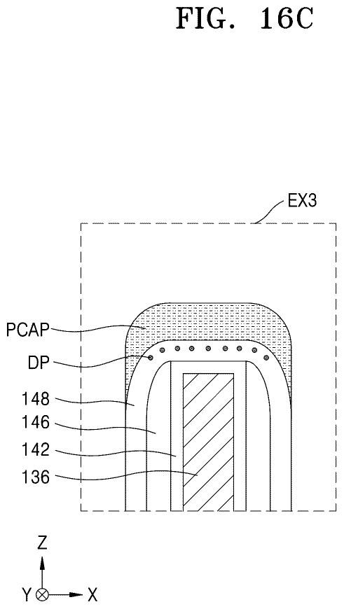

wherein, in detail, each of FIGS. 5A to 21A is a schematic cross-sectional view of some components according to the process sequence of a region corresponding to the cross-section of the integrated circuit device shown in FIG. 1 taken along a line A-A′ of FIG. 1, and each of FIGS. 5B to 21B is a schematic cross-sectional view of some components according to the process sequence of a region corresponding to the cross-section of the integrated circuit device shown in FIG. 1 taken along a line B-B′ of FIG. 1; and FIG. 15C is an enlarged cross-sectional view of a region EX2 of FIG. 15A, and FIG. 16C is an enlarged view of a region EX3 of FIG. 16A.

### DETAILED DESCRIPTION

FIG. 1 is a schematic layout diagram (i.e., top plan view) of an integrated circuit device according to one or more embodiments.

Referring to FIG. 1, an integrated circuit device 10 may include a plurality of active regions ACT. The plurality of active regions ACT may be arranged in a diagonal direction with respect to a first horizontal direction X and a second horizontal direction Y.

A plurality of word lines WL may extend parallel to one another in the first horizontal direction X across the plurality of active regions ACT. A plurality of bit lines BL may extend parallel to one another in the second horizontal direction Y crossing (i.e., intersecting) the first horizontal direction X over the plurality of word lines WL. The plurality of bit lines BL may be connected to the plurality of active regions ACT via direct contacts DC. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

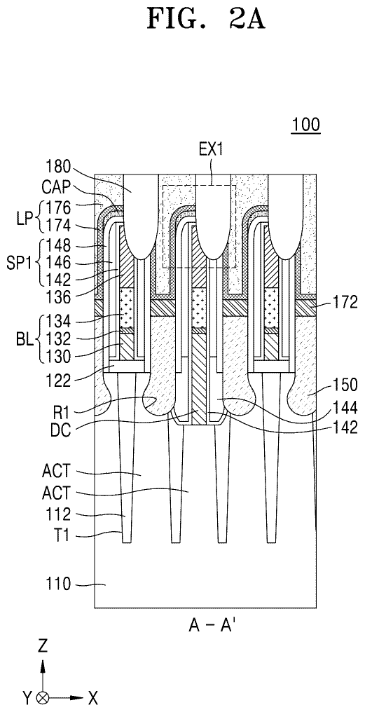

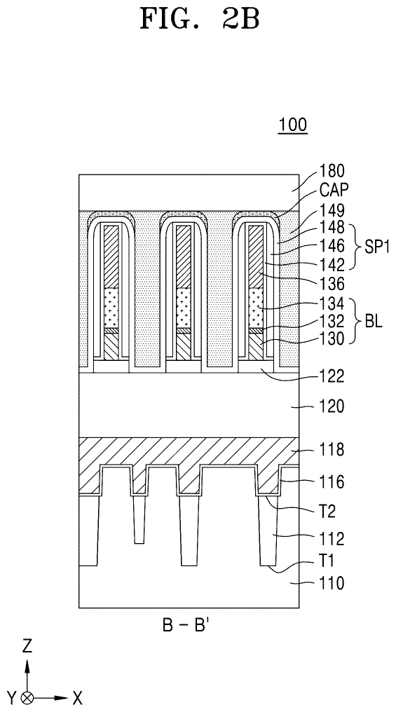

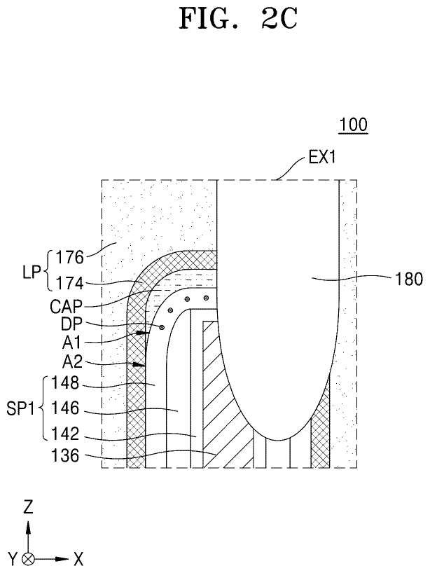

A plurality of buried contacts BC may be formed between two bit lines BL adjacent to each other from among the plurality of bit lines BL. According to embodiments, the plurality of buried contacts BC may be linearly arranged in the first horizontal direction X and the second horizontal direction Y. A plurality of conductive landing pads LP may be respectively formed on the plurality of buried contacts BC. The buried contacts BC and the conductive landing pads LP may connect bottom electrodes (not shown) of capacitors formed over the plurality of bit lines BL to the active regions ACT. At least some of the plurality of conductive landing pads LP may each overlap the buried contact BC in a vertical direction. The term “overlap” (or “overlapping,” or like terms), as may be used herein, is intended to broadly refer to a first element that intersects with at least a portion of a second element in the vertical direction (i.e., direction Z in FIG. 2A), but does not require that the first and second elements be completely aligned with one another in a horizontal plane (i.e., in the first horizontal direction X and/or the second horizontal direction Y).

Next, example configurations of integrated circuit elements according to embodiments will be described with reference to FIGS. 2A, 2B and 2C. An integrated circuit device shown in FIGS. 2A and 2B may have the layout of the integrated circuit device 10 shown in FIG. 1.

FIG. 2A is a schematic cross-sectional view of the integrated circuit device shown in FIG. 1, taken along line A-A′ in FIG. 1.

FIG. 2B is a schematic cross-sectional view of the integrated circuit device shown in FIG. 1, taken along line B-B′ in FIG. 1.

FIG. 2C is an enlarged cross-sectional view of a region EX1 of FIG. 2A.

Referring to FIGS. 2A, 2B and 2C, an integrated circuit device 100 includes a substrate 110 in which a plurality of active regions ACT are defined by a device isolation layer 112. The device isolation layer 112 is formed within a device isolation trench T1 formed in the substrate 110.

The substrate 110 may include silicon, e.g., monocrystalline silicon, polycrystalline silicon, or amorphous silicon, although embodiments are not limited thereto. According to other embodiments, the substrate 110 may include at least one material selected from among Ge, SiGe, SiC, GaAs, InAs, and InP, although embodiments are not limited thereto. According to embodiments, the substrate 110 may include conductive regions, e.g., wells doped with an impurity or structures doped with an impurity. The device isolation layer 112 may include an oxide film, a nitride film, or a combination thereof, although embodiments are not limited thereto.

A plurality of word line trenches T2 extending in the first horizontal direction X are formed in the substrate 110, and, within the plurality of word line trenches T2, a plurality of gate dielectric layers 116, a plurality of word lines 118, and a plurality of buried insulation layers 120 are formed. The plurality of word lines 118 may correspond to the plurality of word lines WL shown in FIG. 1.

The gate dielectric layer 116 may include at least one material selected from among a silicon oxide film, a silicon nitride film, a silicon oxynitride film, an oxide/nitride/oxide (ONO) film, and a high-dielectric constant (high-k) dielectric film having a dielectric constant higher than that of the silicon oxide film, although embodiments are not limited thereto. The high-k dielectric film may include, for example, hafnium oxide (HfO₂), aluminum oxide (Al₂O₃), hafnium aluminum oxide (HfAlO₃), tantalum oxide (Ta₂O₃), titanium oxide (TiO₂), or a combination thereof. The plurality of word lines 118 may include, for example, titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. The plurality of buried insulation layers 120 may each include a silicon oxide film, a silicon nitride film, a silicon oxynitride film, or a combination thereof, although embodiments are not limited thereto.

A buffer layer 122 is formed on the substrate 110. The buffer layer 122 may be formed to cover top surfaces of the plurality of active regions ACT, the top surface of the device isolation layer 112, and top surfaces of the plurality of buried insulation layers 120. The term “cover” (or “covering,” “covers,” or like terms), as may be used herein, is intended to broadly refer to an element, structure or layer that is on or over another element, structure or layer, either directly or with one or more other intervening elements, structures or layers therebetween. The buffer layer 122 may include a first silicon oxide film, a silicon nitride film, and a second silicon oxide film sequentially formed on the substrate 110, but is not limited thereto.

A plurality of bit lines BL extending parallel to one another in the second horizontal direction Y may be formed on the buffer layer 122. The plurality of bit lines BL are spaced apart from one another in the first horizontal direction X. A direct contact DC is formed on a portion of each of the plurality of active regions ACT. The plurality of bit lines BL may be connected to the plurality of active regions ACT via a plurality of direct contacts DC, respectively. The direct contact DC may include, for example, silicon (Si), germanium (Ge), W, tungsten nitride (WN), cobalt (Co), nickel (Ni), aluminum (Al), molybdenum (Mo), ruthenium (Ru), Ti, Ta, TaN, copper (Cu), or a combination thereof. According to embodiments, the direct contact DC may include a doped polysilicon film.

The plurality of bit lines BL may each include a lower conductive layer 130, an intermediate conductive layer 132, and an upper conductive layer 134 that are sequentially stacked on the substrate 110 in the vertical direction Z. Each of the plurality of bit lines BL is covered by an insulation capping pattern 136. The insulation capping pattern 136 may be disposed above the upper conductive layer 134 in the vertical direction Z. The top surface of the lower conductive layer 130 of the bit line BL and the top surface of the direct contact DC may be arranged on the same plane (i.e., coplanar), relative to the upper surface of the substrate 110 as a reference layer. Although FIGS. 2A and 2B show that each of the plurality of bit lines BL has a triple conductive layer structure including the lower conductive layer 130, the intermediate conductive layer 132, and the upper conductive layer 134, the present inventive concept is not limited thereto. For example, the plurality of bit lines BL may each be formed to include a single conductive layer, include a double conductive layer, or have a stacked structure including a plurality of conductive layers (four or more conductive layers).

According to embodiments, the lower conductive layer 130 may include a doped polysilicon film. The intermediate conductive layer 132 and the upper conductive layer 134 may each include a film containing Ti, TiN, TiSiN, tungsten (W), WN, tungsten silicide (WSiₓ), tungsten silicon nitride (WSiₓN_{y}), ruthenium (Ru), or a combination thereof. For example, the intermediate conductive layer 132 may include a TiN film and/or a TiSiN film, and the upper conductive layer 134 may include a film containing Ti, TiN, W, WN, WSiₓN_{y}, Ru, or a combination thereof. The insulation capping pattern 136 may include a silicon nitride film.

A plurality of recess spaces R1 may be formed in the active region ACT in a portion of the substrate 110. A plurality of contact plugs 150 may be arranged in the plurality of recess spaces R1. The plurality of contact plugs 150 may each contact one active region ACT selected from among the plurality of active regions ACT. Lower ends of the plurality of contact plugs 150 may be arranged at a vertical level lower than that of the top surface of the substrate 110 such that the lower ends of the plurality of contact plugs 150 are buried in the substrate 110. As used herein, the term “vertical level” refers to a height in a vertical direction Z or −Z. The plurality of contact plugs 150 may include a semiconductor material doped with an impurity, a metal, a conductive metal nitride, or a combination thereof, but the present inventive concept is not limited thereto.

In the integrated circuit device 100, one direct contact DC and a pair of contact plugs 150 facing each other with the one direct contact DC therebetween may be respectively connected to different active regions ACT from among the plurality of active regions ACT. According to an embodiment, when the direct contact DC is connected to a first active region ACT selected from among the plurality of active regions ACT, a pair of contact plugs 150 facing each other with the direct contact DC therebetween may be respectively connected to a second active region ACT and a third active region ACT adjacent to the first active region ACT.

The plurality of contact plugs 150 may be linearly arranged in the second horizontal direction Y between a pair of bit lines BL adjacent to each other from among the plurality of bit lines BL. A plurality of insulation fences 149 may be arranged between the plurality of contact plugs 150 linearly arranged in the second horizontal direction Y. The plurality of contact plugs 150 may be insulated from one another by the plurality of insulation fences 149. The plurality of insulation fences 149 may each have a pillar-like shape extending in the vertical direction Z on the substrate 110. According to embodiments, the plurality of insulation fences 149 may each include a silicon nitride film.

The integrated circuit device 100 may include a plurality of spacer structures SP1 between the plurality of bit lines BL and the plurality of conductive landing pads LP and between the plurality of bit lines BL and the plurality of contact plugs 150. For example, one spacer structure SP1 may be provided between one bit line BL selected from among the plurality of bit lines BL and the plurality of contact plugs 150 arranged in a row in the second horizontal direction Y. The plurality of spacer structures SP1 may each include an inner insulation spacer 142, an intermediate insulation spacer 146, an outer insulation spacer 148, and an insulation capping film CAP.

The inner insulation spacer 142 may contact the sidewall of the direct contact DC and the sidewall of the lower conductive layer 130 of the bit line BL. The inner insulation spacer 142 may extend in the vertical direction Z along the sidewalls of the intermediate conductive layer 132 and the upper conductive layer 134 of the bit line BL. The inner insulation spacer 142 may cover from the highest level of both sidewalls of the insulation capping pattern 136 on the bit line BL to the lowest level of both sidewalls of the lower conductive layer 130 of the bit line BL in the vertical direction Z. Also, the inner insulation spacer 142 may cover from the highest level of both sidewalls of the insulation capping pattern 136 on the direct contact DC to the lowest level of both sidewalls of the direct contact DC in the vertical direction Z. The inner insulation spacer 142 may cover the top surface of the insulation capping pattern 136. Also, the inner insulation spacer 142 may surround the lower portion of a gap fill insulation pattern 144 and extend until the inner insulation spacer 142 contacts the lower end of the adjacent contact plug 150. Alternatively, the inner insulation spacer 142 may surround (i.e., extend around) the lower portion of the intermediate insulation spacer 146 and extend until the inner insulation spacer 142 contacts the sidewall of the outer insulation spacer 148. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The inner insulation spacer 142 may include a nitride film, e.g., a silicon nitride film.

The intermediate insulation spacer 146 may extend in the vertical direction Z along the sidewall of the inner insulation spacer 142. The bottom surface of the intermediate insulation spacer 146 may be surrounded by the inner insulation spacer 142 or the gap fill insulation pattern 144. The intermediate insulation spacer 146 may be provided between the inner insulation spacer 142 and the outer insulation spacer 148. The intermediate insulation spacer 146 may be spaced apart from the bit line BL and the direct contact DC with the inner insulation spacer 142 therebetween. The intermediate insulation spacer 146 may include a silicon oxide film, an air spacer, or a combination thereof. The term “air” used herein may refer to the atmosphere or other gases that may be present during a manufacturing process.

The gap fill insulation pattern 144 may be provided between the lower end of the contact plug 150 and the direct contact DC. Compared to a portion of the gap fill insulation pattern 144 provided between the outer insulation spacer 148 and the inner insulation spacer 142, a portion of the gap fill insulation pattern 144 provided between the contact plug 150 and the inner insulation spacer 142 may be formed to be thicker in a horizontal direction (e.g., the first horizontal direction X). One sidewall of the gap fill insulation pattern 144 may be covered by the lower end of the contact plug 150. The other sidewalls and the bottom surface of the gap fill insulation pattern 144 may be surrounded by the inner insulation spacer 142.

The outer insulation spacer 148 may cover a portion of the sidewall of the contact plug 150. In detail, the outer insulation spacer 148 may cover a portion of the sidewall of the contact plug 150 that is not buried in the substrate 110. The outer insulation spacer 148 may cover a portion of the sidewall of the contact plug 150 adjacent and extend to cover the sidewall and the top surface of the intermediate insulation spacer 146 and the top surface of the inner insulation spacer 142. In other words, the outer insulation spacer 148 may include a portion that overlaps the bit line BL, the insulation capping pattern 136, the inner insulation spacer 142, and the intermediate insulation spacer 146 in the vertical direction Z.

The outer insulation spacer 148 may be spaced apart from the bit line BL in the first horizontal direction X with the inner insulation spacer 142 and the intermediate insulation spacer 146 therebetween. The outer insulation spacer 148 may be spaced apart from the direct contact DC in the first horizontal direction X with the inner insulation spacer 142 and the intermediate insulation spacer 146 therebetween. Also, the outer insulation spacer 148 may be spaced apart from the bit line BL in the vertical direction Z with the insulation capping pattern 136 and the inner insulation spacer 142 therebetween.

According to embodiments, the outer insulation spacer 148 may include a dopant DP and may include a silicon nitride film including the dopant DP. The dopant DP may include a metal, e.g., Al, Ga, In, Ti, Sn, Pb, Cu, or Fe, although embodiments are not limited thereto. In the present specification, a portion of the outer insulation spacer 148 that includes the dopant DP may be referred to as a doped region A1, and a portion of the outer insulation spacers 148 that do not contain the dopant DP may be referred to as an undoped region A2. According to embodiments, the doped region A1 may further include a dopant DP other than Si and N, and the undoped region A2 may include Si and N. Since the doped region A1 includes the dopant DP and the dopant DP may include a metal, the doped region A1 may exhibit higher etching resistance than the undoped region A2.

According to embodiments, the doped region A1 of the outer insulation spacer 148 may be a resultant structure of performing an ion implantation process on the top surface of the outer insulation spacer 148. In this case, as shown in FIG. 2C, the upper portion of the outer insulation spacer 148 may include the doped region A1, and the lower portion of the outer insulation spacer 148 may include the undoped region A2.

The insulation capping film CAP may be disposed on the outer insulation spacer 148 (e.g., on at least a portion of the doped region A1 of the outer insulation spacer 148). The insulation capping film CAP may be between at least a portion of the outer insulation spacer 148 and the conductive landing pad LP to space the conductive landing pad LP from the top of the outer insulation spacer 148. The sidewall of the insulation capping film CAP and the sidewall of the outer insulation spacer 148 may contact the sidewall of the conductive landing pad LP. According to embodiments, the insulation capping film CAP may have a shape in which the thickness of the insulation capping film CAP (between the outer insulation spacer 148 and the conductive landing pad LP) decreases from the center of the insulation capping film CAP toward the edge of the insulation capping film CAP.

According to embodiments, the step coverage of the insulation capping film CAP may be lower than the step coverage of the outer insulation spacer 148. According to an embodiment, the insulation capping film CAP may cover the top surface of the outer insulation spacer 148, as shown in FIGS. 2A and 2B, and may not extend onto the sidewall of the outer insulation spacer 148. In other words, the sidewall of the outer insulation spacer 148 and the sidewall of the insulation capping film CAP may be located on the same plane. According to another embodiment, the insulation capping film CAP may cover the top surface of the outer insulation spacer 148 and partially extend onto the sidewall of the outer insulation spacer 148. The insulation capping film CAP may cover the doped region A1 of the outer insulation spacer 148.

The insulation capping film CAP may include a silicon nitride film. According to embodiments, the insulation capping film CAP may be a product obtained by depositing a silicon precursor and a nitrogen precursor through a plasma enhanced atomic layer deposition (PEALD) process, although embodiments are not limited thereto.

The inner insulation spacer 142, the intermediate insulation spacer 146, the outer insulation spacer 148, and the insulation capping film CAP constituting each of the plurality of spacer structures SP1 may extend in the second horizontal direction Y in parallel with the bit line BL.

A metal silicide film 172 and the plurality of conductive landing pads LP may be sequentially arranged on the plurality of contact plugs 150. The plurality of conductive landing pads LP may be connected to the plurality of contact plugs 150 through the metal silicide film 172. The plurality of conductive landing pads LP may extend from spaces between a plurality of insulation capping patterns 136 onto the top of the plurality of insulation capping patterns 136 to overlap some of the plurality of bit lines BL in the vertical direction Z. The plurality of conductive landing pads LP may each include a conductive barrier film 174 and a conductive layer 176.

According to embodiments, the insulation capping film CAP may be provided between the conductive landing pad LP and the outer insulation spacer 148. A portion of the conductive landing pad LP that overlaps the outer insulation spacer 148 in the vertical direction Z may be spaced apart from the outer insulation spacer 148 with the insulation capping film CAP therebetween. The conductive landing pad LP extends along the outer insulation spacer 148, contacts the side of the outer insulation spacer 148, and may be spaced apart from the top of the outer insulation spacer 148 with the insulation capping film CAP therebetween.

According to embodiments, the metal silicide film 172 may include cobalt silicide, nickel silicide, or manganese silicide, but is not limited thereto. According to some embodiments, the metal silicide film 172 may be omitted. The conductive barrier film 174 may have a Ti/TiN stacked structure. The conductive layer 176 may include doped polysilicon, a metal, a metal silicide, a conductive metal nitride, or a combination thereof. For example, the conductive layer 176 may include tungsten (W). The plurality of conductive landing pads LP may have a pattern shape like a plurality of islands when viewed from above (i.e., in plan view). The plurality of conductive landing pads LP may be electrically insulated from one another by an insulation film 180 that fills the space around them. The term “fills” (or “filling,” “filled,” or like terms), as may be used herein, is intended to refer broadly to either completely filling a defined space (e.g., the space around the conductive landing pads LP) or partially filling the defined space; that is, the defined space need not be entirely filled but may, for example, be partially filled or have voids or other spaces throughout. FIG. 2A shows an example in which a triple conductive layer structure including the metal silicide film 172, the conductive barrier film 174, and the conductive layer 176 is disposed on each of the plurality of contact plugs 150, but the present inventive concept is not limited thereto. For example, only a single conductive layer may be disposed on each of the plurality of contact plugs 150.

According to embodiments, since the outer insulation spacer 148 includes the doped region Al with improved etching resistance, and thus a doped portion of the outer insulation spacer 148 and the insulation capping pattern 136, the inner insulation spacer 142, and the intermediate insulation spacer 146 surrounded by the outer insulation spacer 148 may be prevented from being consumed together during an etching process for forming the contact plug 150.

Also, since the insulation capping film CAP is disposed on the outer insulation spacer 148, the outer insulation spacer 148 may be prevented from being consumed together during an etching process for forming the contact plug 150. As a result, a leakage current between the landing pad LP and the bit line BL that occurs when the insulation capping pattern 136, the inner insulation spacer 142, the intermediate insulation spacer 146, and the outer insulation spacer 148 are consumed through an etching process may be prevented, and thus an integrated circuit device with improved reliability may be provided.

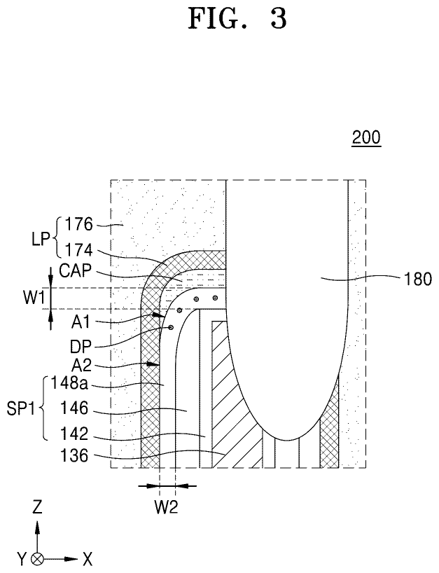

FIG. 3 is a schematic diagram of an integrated circuit device 200 according to other

embodiments. FIG. 3 shows a portion corresponding to a region “EX1” of FIG. 2A. The integrated circuit device 200 differs from the integrated circuit device 100 shown in FIGS. 2A,2B and 2C only in that the integrated circuit device 200 includes an outer insulation spacer 148a instead of the outer insulation spacer 148, and thus descriptions below will focus on the differences between the integrated circuit device 100 and the integrated circuit device 200.

Referring to FIG. 3, the plurality of spacer structures SP1 may each include the inner insulation spacer 142, the intermediate insulation spacer 146, the outer insulation spacer 148a, and the insulation capping film CAP.

The outer insulation spacer 148a may cover a portion of the sidewall of the contact plug 150. In detail, the outer insulation spacer 148a may cover a portion of the sidewall of the contact plug 150 that is not buried in the substrate 110. The outer insulation spacer 148a may cover a portion of the sidewall of the adjacent contact plug 150 and extend to cover the sidewall and the top surface of the intermediate insulation spacer 146 and the top surface of the inner insulation spacer 142. In other words, the outer insulation spacer 148a may include a portion that overlaps the bit line BL, the insulation capping pattern 136, the inner insulation spacer 142, and the intermediate insulation spacer 146 in the vertical direction Z.

The outer insulation spacer 148a may be spaced apart from the bit line BL in the first horizontal direction X with the inner insulation spacer 142 and the intermediate insulation spacer 146 therebetween. The outer insulation spacer 148a may be spaced apart from the direct contact DC (see FIG. 2A) in the first horizontal direction X with the inner insulation spacer 142 and the intermediate insulation spacer 146 therebetween. Also, the outer insulation spacer 148a may be spaced apart from the bit line BL (see FIG. 2A) in the vertical direction Z with the insulation capping pattern 136 and the inner insulation spacer 142 therebetween.

According to embodiments, the outer insulation spacer 148a may include a dopant DP and may include a silicon nitride film including the dopant DP, although embodiments are not limited thereto. The dopant DP may include a metal, e.g., Al, Ga, In, Ti, Sn, Pb, Cu, or Fe. In the present specification, a portion of the outer insulation spacer 148a that includes the dopant DP may be referred to as a doped region A1, and a portion of the outer insulation spacer 148a that does not include the dopant DP may be referred to as an undoped region A2. According to embodiments, the doped region A1 may further include a dopant DP other than Si and N, and the undoped region A2 may include Si and N. Since the doped region A1 includes the dopant DP and the dopant DP includes a metal, the doped region A1 may exhibit higher etching resistance than the undoped region A2.

According to embodiments, the doped region A1 of the outer insulation spacer 148a may be a resultant structure of performing an ion implantation process on the top surface of the outer insulation spacer 148a. In this case, as shown in FIG. 3, the upper portion of the outer insulation spacer 148a may include the doped region A1 and the lower portion of the outer insulation spacer 148a may include the undoped region A2.

According to embodiments, a thickness W1 of the doped region A1 of the outer insulation spacer 148a in the vertical direction Z may be greater than a thickness W2 of the undoped region A2 of the outer insulation spacer 148a in the first horizontal direction X. For example, the thickness W1 of the doped region A1 of the outer insulation spacer 148a may be within a range from about 3 nanometers to about 5 nanometers, and the thickness W2 of the undoped region A2 of the outer insulation spacer 148a may be within a range from about 1 nanometer to about 3 nanometers. For example, when the upper portion of the outer insulation spacer 148a is the doped region A1, the thickness of the upper portion of the outer insulation spacer 148a may be greater than the thickness of the lower portion of the outer insulation spacer 148a.

According to other embodiments, the thickness W1 of a portion of the outer insulation spacer 148a contacting the insulation capping film CAP may be greater than the thickness W2 of a portion of the outer insulation spacer 148a not contacting the insulation capping film CAP. For example, the thickness W1 of the portion of the outer insulation spacer 148a contacting the insulation capping film CAP may be within a range from about 3 nanometers to about 5 nanometers, and the thickness of the portion of the outer insulation spacer 148a not contacting the insulation capping film CAP may be within a range from about 1 nanometer to about 3 nanometers. For example, when the upper portion of the outer insulation spacer 148a is covered by the insulation capping film CAP, the thickness of the upper portion of the outer insulation spacer 148a may be greater than the thickness of the lower portion of the outer insulation spacer 148a. A portion of the outer insulation spacer 148a contacting the insulation capping film CAP may overlap the doped region A1 of the outer insulation spacer 148a.

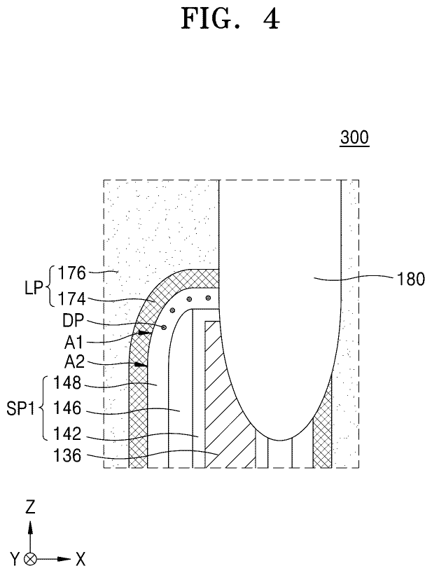

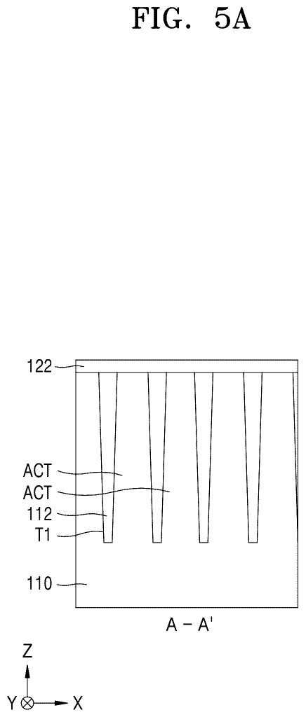

FIG. 4 is a schematic diagram of an integrated circuit device 300 according to other embodiments. FIG. 4 shows a portion of the integrated circuit device shown in FIG. 2A corresponding to a region “EX1” of FIG. 2A. Since the integrated circuit device 300 does not include the insulation capping film CAP unlike the integrated circuit device 100 shown in FIGS. 2A, 2B and 2C, descriptions below will focus on the differences between the integrated circuit device 100 and the integrated circuit device 300.

Referring to FIG. 4, the plurality of spacer structures SP1 may each include the inner insulation spacer 142, the intermediate insulation spacer 146, and the outer insulation spacer 148.

The inner insulation spacer 142, the intermediate insulation spacer 146, and the outer insulation spacer 148 constituting each of the plurality of spacer structures SP1 may extend in the second horizontal direction Y in parallel with the bit line BL (see FIG. 2A).

In the case of the integrated circuit device 300 shown in FIG. 4, the insulation capping film CAP may not be disposed on the outer insulation spacer 148 unlike in the integrated circuit device 100 shown in FIGS. 2A, 2B and 2C. In other words, the insulation capping film CAP may not be provided between the outer insulation spacer 148 and the conductive barrier film 174.

According to embodiments, the integrated circuit device 300 shown in FIG. 4 may be a resultant structure obtained as the insulation capping film CAP is completely consumed through an etching process to form the contact plug 150 in FIGS. 2A, 2B and 2C.

According to embodiments, the conductive landing pad LP may be positioned on the outer insulation spacer 148 with no other component between the outer insulation spacer 148 and the conductive landing pad LP, and thus the outer insulation spacer 148 may be in direct contact with the conductive landing pad LP (i.e., without any intervening layer therebetween). For example, a portion of the conductive landing pad LP that overlaps the outer insulation spacer 148 in the vertical direction Z may contact the outer insulation spacer 148. The conductive landing pad LP extends along the side of the outer insulation spacer 148, contacts the side of the outer insulation spacer 148, and may cover the top of the outer insulation spacer 148.

The plurality of conductive landing pads LP may each include a conductive barrier film 174 and a conductive layer 176. For example, a portion of the conductive barrier film 174 that overlaps the outer insulation spacer 148 in the vertical direction Z may contact the outer insulation spacer 148. The conductive barrier film 174 extends along the side of the outer insulation spacer 148, contacts the side of the outer insulation spacer 148, and may cover the top of the outer insulation spacer 148.

Like the integrated circuit device 100 described with reference to FIGS. 2A, 2B and 2C, since integrated circuit devices 200 and 300 described with reference to FIGS. 3 and 4, respectively, each include the outer insulation spacer 148 with improved etching resistance, the doped region A1 of the outer insulation spacer 148 and the insulation capping pattern 136, the inner insulation spacer 142, and the intermediate insulation spacer 146 surrounded by the outer insulation spacer 148 may be prevented from being consumed together during an etching process for forming the plurality of contact plugs 150.

Also, in the integrated circuit device 200 shown in FIG. 3, the insulation capping film CAP is disposed on the outer insulation spacer 148, and thus the outer insulation spacer 148 may be prevented from being consumed during an etching process for forming the plurality of contact plugs 150.

As a result, a leakage current between the landing pad LP and the bit line BL that occurs when the insulation capping pattern 136, the inner insulation spacer 142, the intermediate insulation spacer 146, and the outer insulation spacer 148 are consumed through an etching process may be prevented, and thus an integrated circuit device with improved reliability may be provided.

FIGS. 5A, 5B to 14A, 14B, 15A, 15B, 15C, 16A, 16B, 16C and 17A, 17B to 21A, 21B are schematic diagrams depicting intermediate processes in an example method of manufacturing an integrated circuit device according to embodiments.

In detail, each of FIGS. 5A to 21A is a schematic cross-sectional view of some components according to the process sequence of a region corresponding to the cross-section of the illustrative integrated circuit device 10 shown in FIG. 1, taken along a line A-A′ of FIG. 1 and each of FIGS. 5B to 21B is a schematic cross-sectional view of some components according to the process sequence of a region corresponding to the cross-section of the illustrative integrated circuit device 10 shown in FIG. 1, taken along a line B-B′ of FIG. 1. FIG. 15C is an enlarged view of a region EX2 in FIG. 15A, and FIG. 16C is an enlarged view of a region EX3 in FIG. 16A.

Hereinafter, a method of manufacturing the integrated circuit device 100 shown in FIGS. 2A, 2B and 2C will be described with reference to FIGS. 5A, 5B to 14A, 14B, 15A, 15B, 15C, 16A, 16B, 16C and 17A, 17B to 21A, 21B.

Referring to FIGS. 5A and 5B, the device isolation trench T1 may be formed in the substrate 110, and the device isolation layer 112 may be formed within the device isolation trench T1. The plurality of active regions ACT may be defined in the substrate 110 by the device isolation layer 112.

The plurality of word line trenches T2 may be formed in the substrate 110. The plurality of word line trenches T2 may be spaced apart from one another in the first horizontal direction X and may extend parallel to each other in the second horizontal direction Y and may have a linear shape extending across the active region ACT. To form the plurality of word line trenches T2 in which steps are formed at the bottom surfaces thereof, the device isolation layer 112 and the substrate 110 may be respectively etched in separate etching processes such that the device isolation layer 112 and the substrate 110 are etched to different depths. After cleaning a resultant structure in which the plurality of word line trenches T2 are formed, the gate dielectric layer 116, a word line 118, and a buried insulation layer 120 may be sequentially formed inside each of the plurality of word line trenches T2. Before or after forming the plurality of word lines 118, an ion implantation process may be performed to form a plurality of source/drain regions (not explicitly shown) on the plurality of active regions ACT.

The buffer layer 122 may be formed on the substrate 110. The buffer layer 122 may be formed to cover top surfaces of the plurality of active regions ACT, the top surface of the device isolation layer 112, and top surfaces of the plurality of buried insulation layers 120. To form the buffer layer 122, a first silicon oxide film, a silicon nitride film, and a second silicon oxide film may be sequentially formed on the substrate 110, but the present inventive concept is not limited thereto.

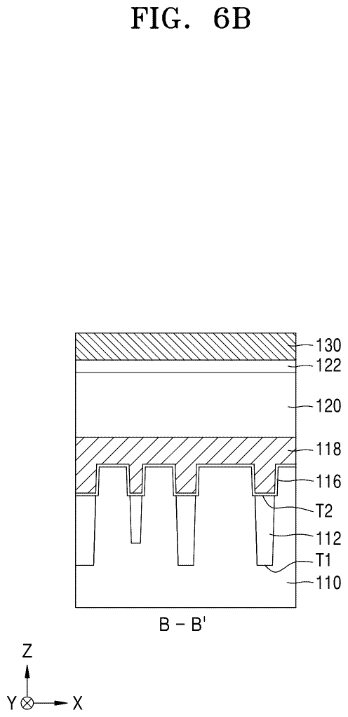

Referring to FIGS. 6A and 6B, the lower conductive layer 130 may be formed on the buffer layer 122. The lower conductive layer 130 may include, for example, a doped polysilicon film, although embodiments are not limited thereto.

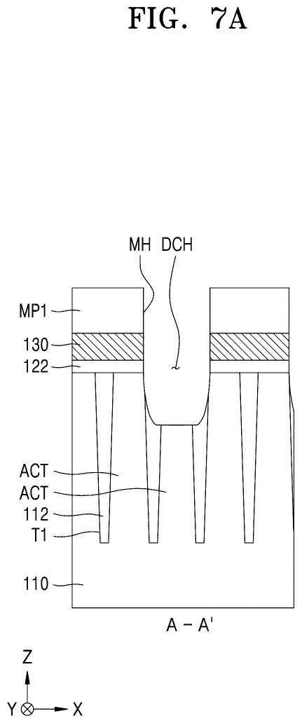

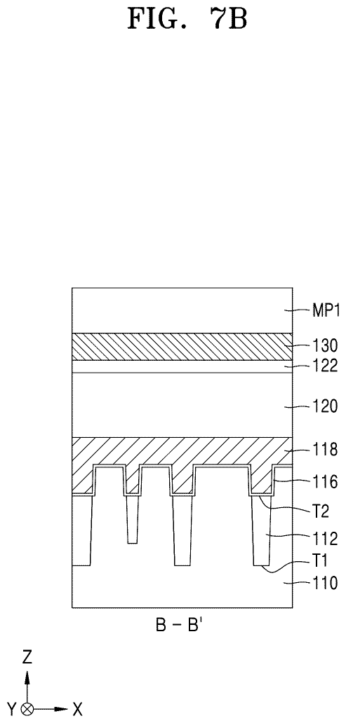

Referring to FIGS. 7A and 7B, after a mask pattern MP1 is formed on the lower conductive layer 130, the lower conductive layer 130 is exposed through an opening MH in the mask pattern MP1, and the exposed lower conductive layer 130 and portions of the buffer layer 122, the substrate 110, and the device isolation layer 112 below the exposed lower conductive layer 130 may be etched to form a direct contact hole DCH exposing the active region ACT of the substrate 110. The term “exposed” (or “exposes,” or like terms) may be used herein to describe relationships between elements and/or with reference to intermediate processes in fabricating an integrated circuit device, but may not require exposure of a particular element in the completed device. Likewise, the term “not exposed” may be used to described relationships between elements and/or with reference to intermediate processes in fabricating an integrated circuit device, but may not require a particular element to be unexposed in the completed device. The mask pattern MP1 may include an oxide film, a nitride film, or a combination thereof, but is not limited thereto.

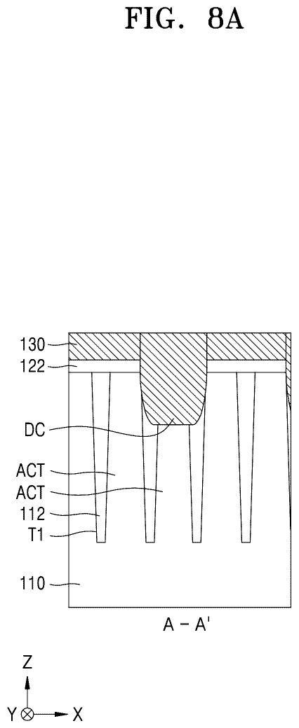

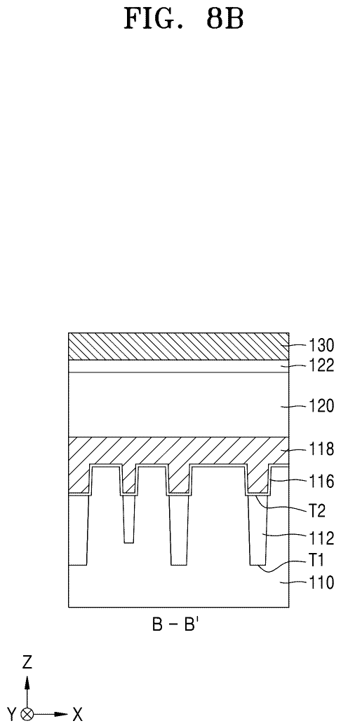

Referring to FIGS. 8A and 8B, the mask pattern MP1 may be removed from a resultant structure of FIGS. 7A and 7B, and the direct contact DC may be formed in the direct contact hole DCH.

To form the direct contact DC, a doped polysilicon film having a thickness sufficient to fill the direct contact hole DCH (see FIG. 7A) may be formed inside the direct contact hole DCH and on the lower conductive layer 130, and unnecessary portions of the doped polysilicon film may be removed such that the doped polysilicon film remains only within the direct contact hole DCH; that is, an upper surface of the direct contact DC and an upper surface of the may be lower conductive layer 130 may be made coplanar with one another (e.g., relative to an upper surface of the substrate 110 as a reference layer), such as, for example, using a chemical-mechanical polishing/planarization (CMP) process. According to embodiments, the direct contact DC may include a polysilicon film doped with an n-type dopant. The n-type dopant may comprise a material selected from among phosphorus (P), arsenic (As), and antimony (Sb), although embodiments are not limited thereto.

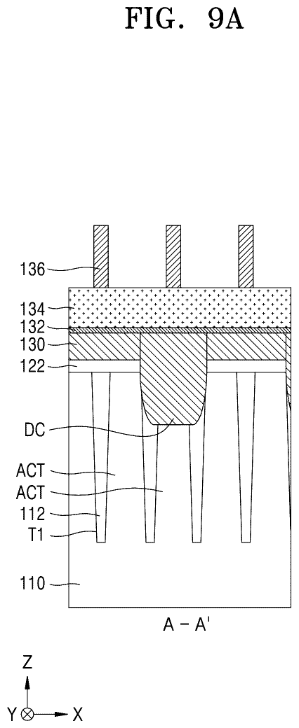

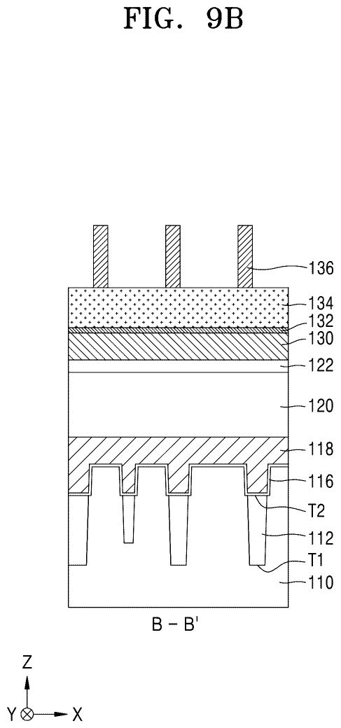

Referring to FIGS. 9A and 9B, the intermediate conductive layer 132, the upper conductive layer 134, and the plurality of insulation capping patterns 136 may be sequentially formed on the lower conductive layer 130 and the direct contacts DC. The plurality of insulation capping patterns 136 may each be formed as a line pattern extending longitudinally in the second horizontal direction Y.

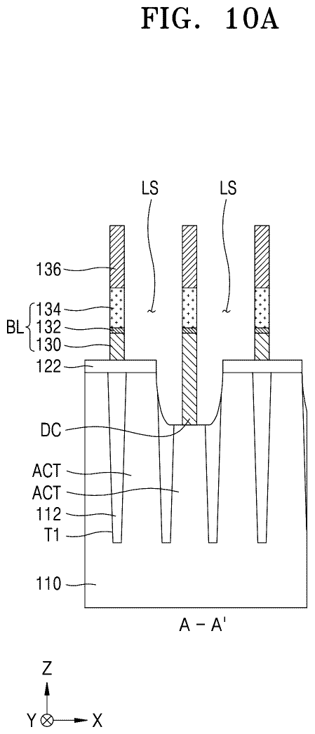

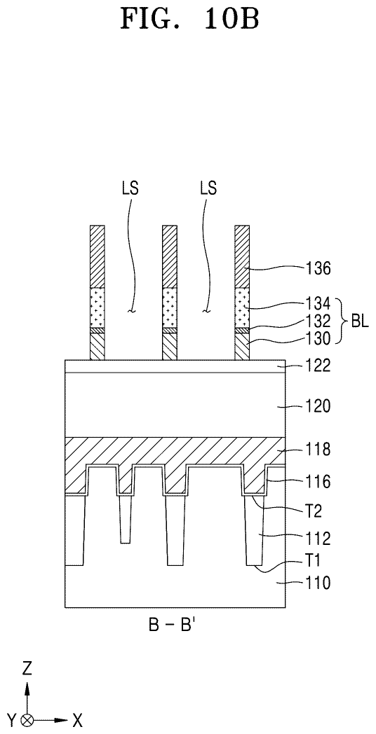

Referring to FIGS. 10A and 10B, in a resultant structure of FIGS. 9A and 9B, portions of the upper conductive layer 134, the intermediate conductive layer 132, the lower conductive layer 130, and the direct contact DC may be etched by using the insulation capping pattern 136 as an etch mask, thereby forming the plurality of bit lines BL on the substrate 110. The plurality of bit lines BL may include remaining portions of the lower conductive layer 130, the intermediate conductive layer 132, and the upper conductive layer 134.

After the plurality of bit lines BL are formed, a portion of the direct contact hole DCH (see FIG. 7A) may be exposed again around the direct contact DC. The bit line BL and the insulation capping pattern 136 may constitute a bit line structure. A line space LS extending longitudinally in the second horizontal direction Y may be defined between the plurality of bit line structures.

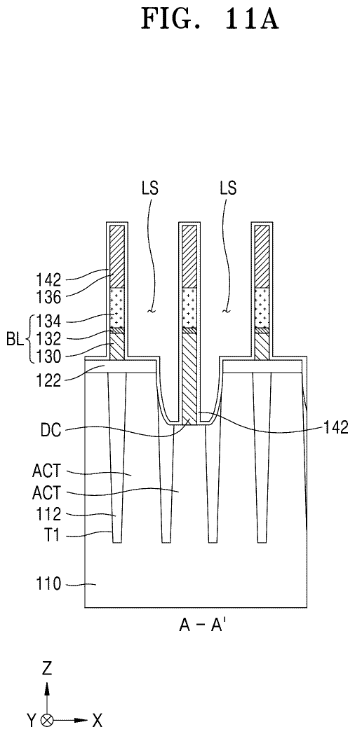

Referring to FIGS. 11A and 11B, the inner insulation spacer 142 may be formed to conformally cover surfaces exposed in a resultant structure of FIGS. 10A and 10B. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied.

The inner insulation spacer 142 may be formed to conformally cover each of the direct contact DC, the lower conductive layer 130, the intermediate conductive layer 132, the upper conductive layer 134, and the plurality of insulation capping patterns 136. The inner insulation spacer 142 may further extend onto at least a portion of an upper surface of the buffer layer 122 and inner sidewalls and a bottom surface of the direct contact hole DCH (see FIG. 7A). The inner insulation spacer 142 may include a silicon nitride film. To form the inner insulation spacer 142, a chemical vapor deposition (CVD) process or an atomic layer deposition (ALD) process may be used.

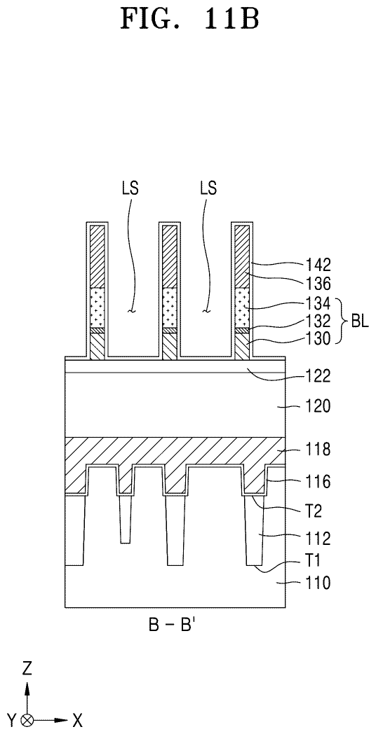

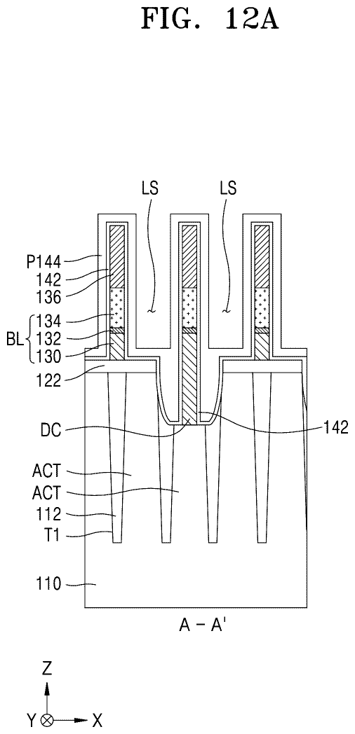

Referring to FIGS. 12A and 12B, a gap fill insulation film P144 that fills the remaining space of the direct contact hole DCH and covers sidewalls of the plurality of bit lines BL, the plurality of insulation capping patterns 136, and the plurality of direct contacts DC may be formed on the inner insulation spacer 142 of the resultant structure shown in FIGS. 11A and 11B.

According to embodiments, the gap fill insulation film P144 may include, for example, a silicon nitride film. A CVD process or an ALD process may be used to form the gap fill insulation film P144.

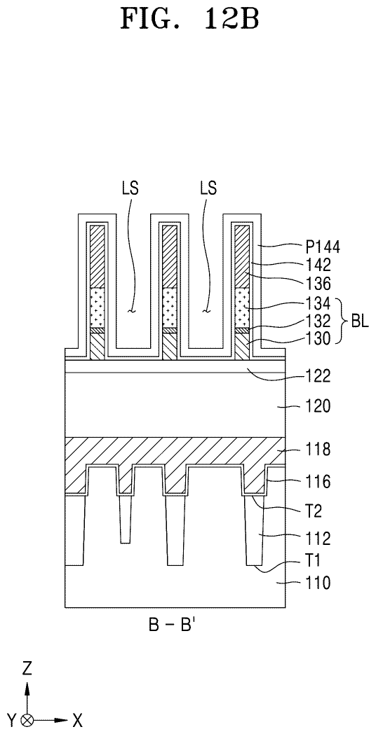

Referring to FIGS. 13A and 13B, the gap fill insulation film P144 in a resultant structure of FIGS. 12A and 12B may be isotropically etched to form the gap fill insulation pattern 144 including the remaining portion of the gap fill insulation film P144 extending around the direct contact DC and filling the direct contact hole DCH. During isotropic etching of the gap fill insulation film P144, the inner insulation spacer 142 may serve as an etch stop layer. The gap fill insulation pattern 144 includes a portion of the gap fill insulation film P144 that fills the inside of the direct contact hole DCH and a portion of the gap fill insulation film P144 that covers the entrance of the direct contact hole DCH from the outside of the entrance side of the direct contact hole DCH.

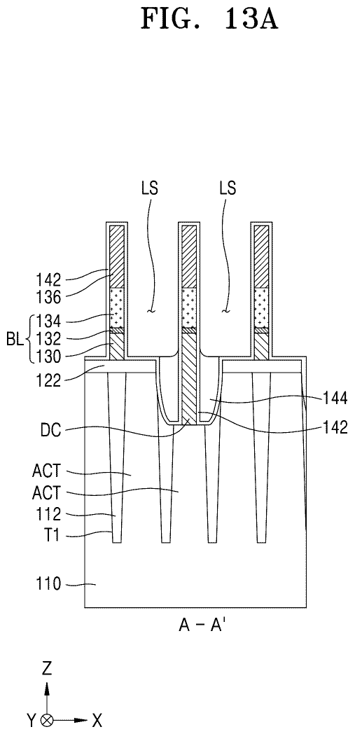

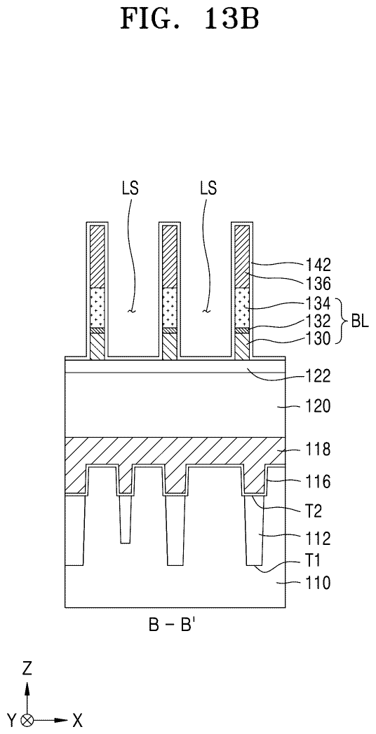

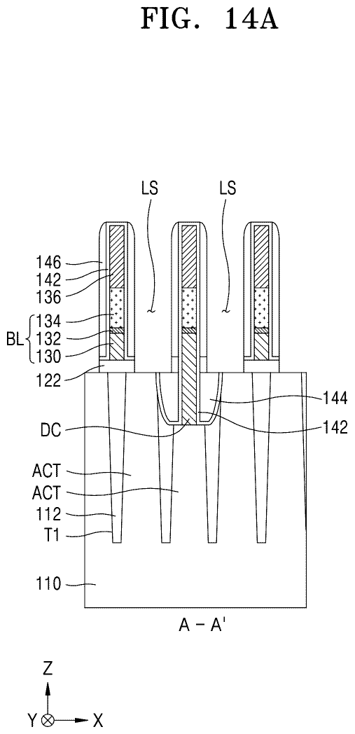

Referring to FIGS. 14A and 14B, after forming an intermediate insulation spacer film that conformally covers surfaces exposed in a resultant structure of FIGS. 13A and 13B through a CVD process or an ALD process, a plurality of intermediate insulation spacers 146 may be formed from the intermediate insulation spacer film by anisotropically etching the intermediate insulation spacer film.

While the intermediate insulation spacer film is anisotropically etched to form the plurality of intermediate insulation spacers 146, a portion of the inner insulation spacer 142 and a portion of the buffer layer 122 may be removed. As a result, a portion of the substrate 110, a portion of the inner insulation spacer 142, and a portion of the gap fill insulation pattern 144 may be exposed through the plurality of line spaces LS. The plurality of intermediate insulation spacers 146 may each cover the sidewall of the bit line BL and the sidewall of the insulation capping pattern 136 on the inner insulation spacer 142.

The plurality of intermediate insulation spacers 146 may include a material different from those constituting the inner insulation spacer 142 and the gap fill insulation pattern 144. The plurality of intermediate insulation spacers 146 may include a material having an etch selectivity with respect to each of the inner insulation spacer 142 and the gap fill insulation pattern 144. For example, the plurality of intermediate insulation spacers 146 may include a silicon oxide film.

Referring to FIGS. 15A, 15B and 15C, an outer insulation spacer 148 that conformally covers a resultant structure of FIGS. 14A and 14B may be formed. The outer insulation spacer 148 may include a material having an etch selectivity with respect to the plurality of intermediate insulation spacers 146. For example, the outer insulation spacer 148 may include a silicon nitride film. To form the outer insulation spacer 148, an ALD process or a PEALD process may be used.

According to embodiments, in the case of forming the outer insulation spacer 148 through an ALD process, the process of forming the outer insulation spacer 148 may include a first operation of forming an adsorption layer of a silicon precursor, a second operation of removing unnecessary by-products by supplying a purge gas including an inert gas such as nitrogen or argon onto a result structure having formed thereon the adsorption layer of the silicon precursor, a third operation of forming a silicon nitride layer by supplying a nitrogen precursor onto the adsorption layer of the silicon precursor, and a fourth operation of removing unnecessary by-products by supplying a purge gas onto a result structure having formed thereon the silicon nitride layer. At this time, the silicon precursor and the nitrogen precursor may be supplied separately to perform an ALD process. For example, the silicon precursor may include any one selected from the group consisting of SiCl₄, Si₂Cl₆, SiH₂Cl₂, SiH₄, Si(C₂H₅O)₄, Si(NCO)₄, and SiH₂I₂, and the nitrogen precursor may include N₂ or NH₃.

According to embodiments, in the case of forming the outer insulation spacer 148 through a PEALD process, the first to fourth operations stated above are performed sequentially, wherein, in the third operation of forming the silicon nitride layer by supplying the nitrogen precursor onto the adsorption layer of the silicon precursor, the nitrogen precursor may be plasmarized to trigger a reaction between molecules of the nitrogen precursor and the adsorption layer of the silicon precursor. For example, the nitrogen precursor may be plasmarized by using a method such as direct current (DC) plasma, alternating current (AC) plasma, capacitively-coupled plasma (CCP), inductively-coupled plasma (ICP), ultra-high density plasma, or radio frequency (RF) plasma.

Thereafter, the plasmarized nitrogen precursor is supplied to the adsorption layer of the silicon precursor, wherein a bias voltage may be applied thereto to apply a downward force such that the plasmarized nitrogen precursor is adsorbed to the adsorption layer of the silicon precursor.

According to an embodiment, SiH₂I₂ may be used as the silicon precursor, N₂ may be used as the nitrogen precursor, and the outer insulation spacer 148 may be formed using the CCP method. At this time, a supply pulse of the silicon precursor may be from about 0.2 seconds to about 0.4 seconds. Plasma power may be performed at a power level from about 500 W to about 700 W, and a plasma power pulse duration may be from about 4 seconds to about 6 seconds.

According to embodiments, a doping process of injecting the dopant DP onto the outer insulation spacer 148 may be further performed. The dopant DP may include a metal, e.g., Al, Ga, In, Ti, Sn, Pb, Cu, or Fe. For example, the doping process may be performed as an ion implantation process. In the case of performing an ion implantation process on the top surface of the outer insulation spacer 148, the upper portion of the outer insulation spacer 148 may include a doped region, and the lower portion of the outer insulation spacer 148 may include an undoped region. The doping process may be performed in-situ.

Referring to FIGS. 16A, 16B and 16C, a preliminary insulation capping film PCAP may be formed on the top of the outer insulation spacer 148. The preliminary insulation capping film PCAP may include the same material as the outer insulation spacer 148. For example, the preliminary insulation capping film PCAP may include a silicon nitride film. According to embodiments, the step coverage of the preliminary insulation capping film PCAP may be lower than the step coverage of the outer insulation spacer 148. According to an embodiment, the preliminary insulation capping film PCAP may be thickly deposited on the top surface of the outer insulation spacer 148 and may not be deposited on the sidewalls of the outer insulation spacer 148, as shown in FIGS. 16A and 16B. According to another embodiment, the preliminary insulation capping film PCAP may be thickly deposited on the top surface of the outer insulation spacer 148 and may be partially deposited on the sidewalls of the outer insulation spacer 148. According to embodiments, a PEALD process may be used to form the preliminary insulation capping film PCAP.

According to embodiments, in the case of forming the preliminary insulation capping film PCAP through a PEALD process, the process of forming the preliminary insulation capping film PCAP may include a first operation of forming an adsorption layer of a silicon precursor, a second operation of removing unnecessary by-products by supplying a purge gas including an inert gas such as nitrogen or argon onto a result structure having formed thereon the adsorption layer of the silicon precursor, a third operation of forming a silicon nitride layer by supplying a nitrogen precursor onto the adsorption layer of the silicon precursor, and a fourth operation of removing unnecessary by-products by supplying a purge gas onto a result structure having formed thereon the silicon nitride layer. At this time, the silicon precursor and the nitrogen precursor may be supplied separately to perform an ALD process. For example, the silicon precursor may include any one selected from the group consisting of SiCl₄, Si₂Cl₆, SiH₂Cl₂, SiH₄, Si(C₂H₅O)₄, and Si(NCO)₄, and the nitrogen precursor may include N₂ or NH₃.

At this time, in the third operation of forming the silicon nitride layer by supplying the nitrogen precursor onto the adsorption layer of the silicon precursor, the nitrogen precursor may be plasmarized to trigger a reaction between molecules of the nitrogen precursor and the adsorption layer of the silicon precursor. The method of plasmarizing the nitrogen precursor is similar to that described above in the description of the outer insulation spacer 148.

Thereafter, the plasmarized nitrogen precursor is supplied to the adsorption layer of the silicon precursor, wherein a bias voltage may be applied thereto to apply a downward force such that the plasmarized nitrogen precursor is adsorbed to the adsorption layer of the silicon precursor.

According to an embodiment, SiH₂I₂ may be used as the silicon precursor, N₂ may be used as the nitrogen precursor, and the preliminary insulation capping film PCAP may be formed using the CCP method. At this time, a supply pulse of the silicon precursor may be from about 0.01 seconds to about 0.2 seconds. Plasma power may be performed at a power level from about 150 W to about 400 W, and a plasma power pulse duration may be from about 0.1 seconds to about 0.2 seconds.

In this specification, for convenience of explanation, the PEALD process for forming the outer insulation spacer 148 is referred to as a first process, and the PEALD process for forming the preliminary insulation capping film PCAP is referred to as a second process. According to embodiments, the supply pulse of the silicon precursor in the second process may be shorter than the supply pulse of the silicon precursor in the first process. For example, the supply pulse of the silicon precursor in the second process may be from about 1/10 to about ⅓ of the supply pulse of the silicon precursor in the first process. Also, the plasma power of the second process may be lower than the plasma power of the first process, and the plasma power pulse of the second process may be shorter than the plasma power pulse of the first process. For example, the plasma power pulse of the second process may be from about 1/50 to about 1/10 of the plasma power pulse of the first process. Since the supply pulse of the silicon precursor in the second process is lower than the supply pulse of the silicon precursor in the first process and the plasma power pulse of the second process is lower than the plasma power pulse of the first process, the preliminary insulation capping film PCAP may be formed mainly on the outer insulation spacer 148.

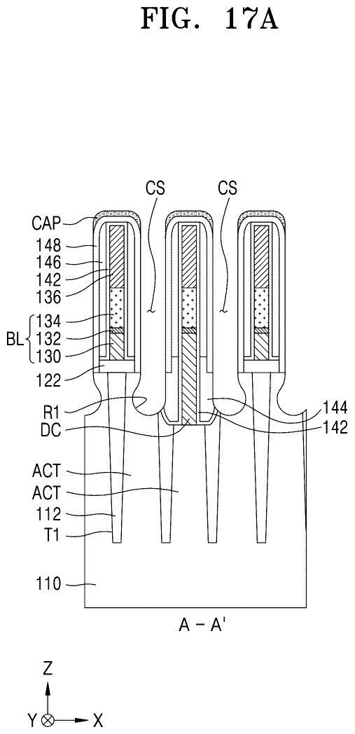

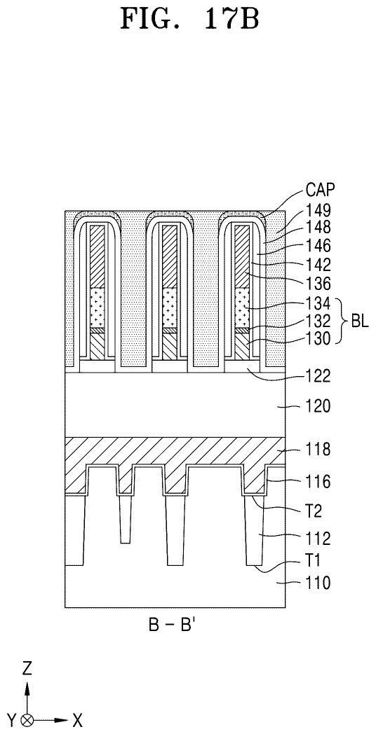

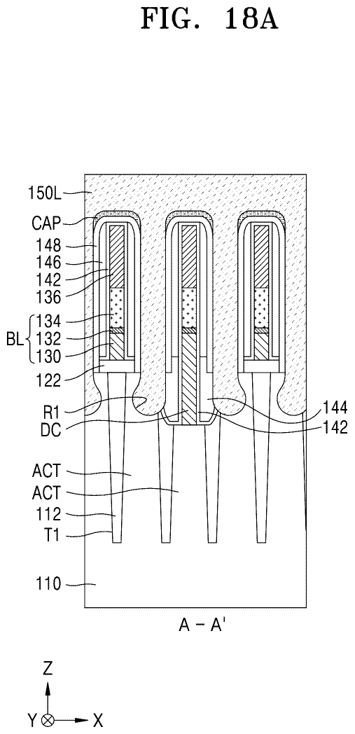

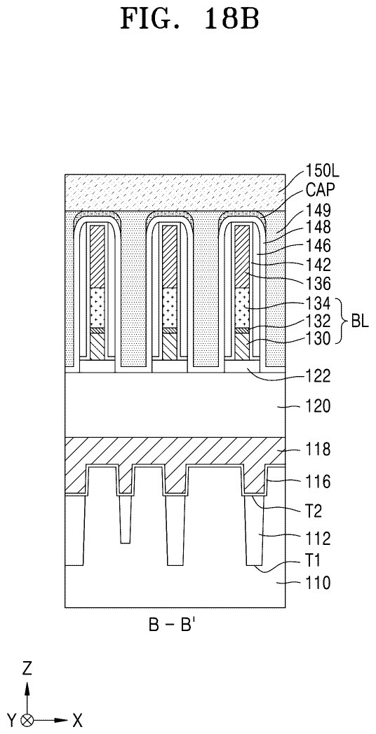

Referring to FIGS. 17A and 17B, in a resultant structure of FIGS. 16A, 16B, and 16C the plurality of insulation fences 149 spaced apart from one another in the first horizontal direction X may be formed in the line space LS defined by the outer insulation spacer 148 between the plurality of bit lines BL, thereby separating the line space LS into a plurality of contact spaces CS.

The plurality of insulation fences 149 may each be formed on the word line 118 to overlap the word line 118 in the vertical direction Z. The plurality of insulation fences 149 may include a silicon nitride film. According to embodiments, while the plurality of insulation fences 149 are being formed, portions of the plurality of insulation capping patterns 136 and insulation films surrounding the plurality of insulation capping patterns 136 may be consumed, and thus heights of the plurality of insulation capping patterns 136 and the insulation films around the plurality of insulation capping patterns 136 may be reduced.

Thereafter, portions of structures exposed through the plurality of contact spaces CS may be removed to form the plurality of recess spaces R1 exposing the plurality of active regions ACT of the substrate 110 between the plurality of bit lines BL. To form the plurality of recess spaces R1, an anisotropic etching process or a combination of an anisotropic etching process and an isotropic etching process may be used. For example, the plurality of recess spaces R1 may be formed by anisotropically etching the outer insulation spacers 148 exposed through the plurality of contact spaces CS between the plurality of bit lines BL and portions of the substrate 110 below the outer insulation spacers 148 and isotropically etching some of the active regions ACT of the substrate 110 that are exposed as a result of the anisotropic etching. The plurality of recess spaces R1 may be connected to the contact spaces CS, respectively. While an etching process is being performed to form the plurality of recess spaces R1, portions of the inner insulation spacer 142 and the gap fill insulation pattern 144 may be consumed in a region adjacent to the top surface of the substrate 110.

A portion of the active region ACT of the substrate 110, a portion of the inner insulation spacer 142, and a portion of the gap fill insulation pattern 144 may be exposed through the plurality of recess spaces R1.

According to embodiments, while the plurality of insulation fences 149 are being formed and an etching process is being performed to form the plurality of recess spaces R1, the preliminary insulation capping film PCAP of FIGS. 16A and 16B may be consumed partially or completely. When the preliminary insulation capping film PCAP is partially consumed, the insulation capping film CAP including the remaining preliminary insulation capping film PCAP may be formed.

According to embodiments, while the plurality of insulation fences 149 are being formed and an etching process is being performed to form the plurality of recess spaces R1, an undoped region of the outer insulation spacer 148 may be consumed. For example, when the upper portion of the outer insulation spacer 148 is doped, the lower portion of the outer insulation spacer 148 may be partially consumed used while the plurality of insulation fences 149 are being formed and an etching process is being performed to form the plurality of recess spaces R1.

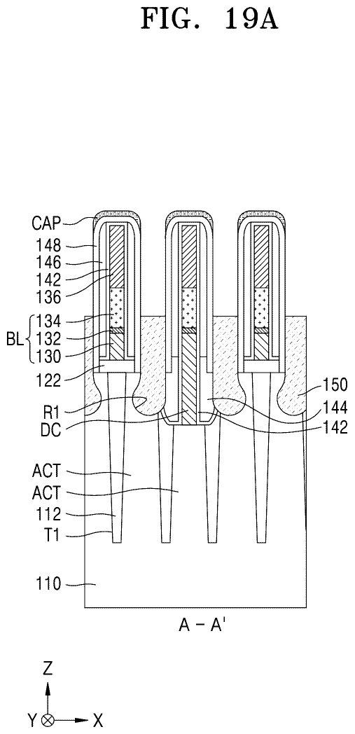

Referring to FIGS. 18A and 18B, in a resultant structure of FIGS. 17A and 17B, a conductive layer 150L may be formed to at least partially fill the plurality of recess spaces R1 and the plurality of contact spaces CS between the plurality of bit lines BL. The conductive layer 150L may include a portion that covers top surfaces of the plurality of insulation capping patterns 136 outside the plurality of contact spaces CS. The conductive layer 150L may include a doped polysilicon film. For example, the conductive layer 150L may include a polysilicon film doped with an n-type dopant, although embodiments are not limited thereto.

According to embodiments, after a doped polysilicon film that fills the plurality of recess spaces R1 and the plurality of contact spaces CS is formed to form the conductive layer 150L, a laser annealing process may be performed to densify (i.e., to make denser) the doped polysilicon film. By performing a laser annealing process on the doped polysilicon film, voids included in the doped polysilicon film may be removed, and thus a doped polysilicon film with dense film quality may be obtained.

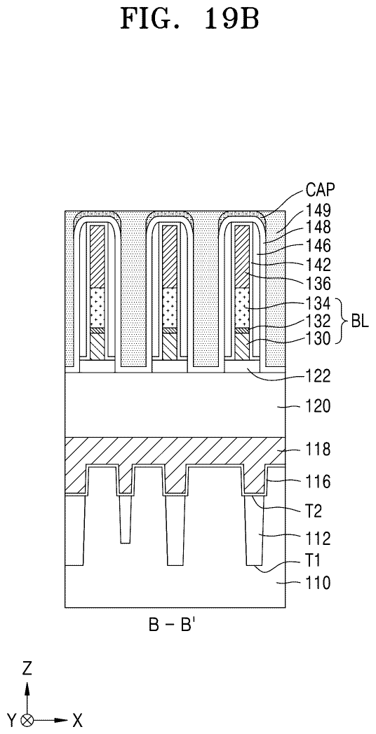

Referring to FIGS. 19A and 19B, in a resultant structure of FIGS. 18A and 18B, the conductive layer 150L may be etched back, thereby forming the plurality of contact plugs 150 that fill the plurality of recess spaces R1 and fill portions of the contact spaces CS between the plurality of bit lines BL. As a result of the etch-back process, an upper surface of the contact plugs 150 may be at a lower level than an upper surface of the insulation capping film CAP, relative to the upper surface of the substrate 110.

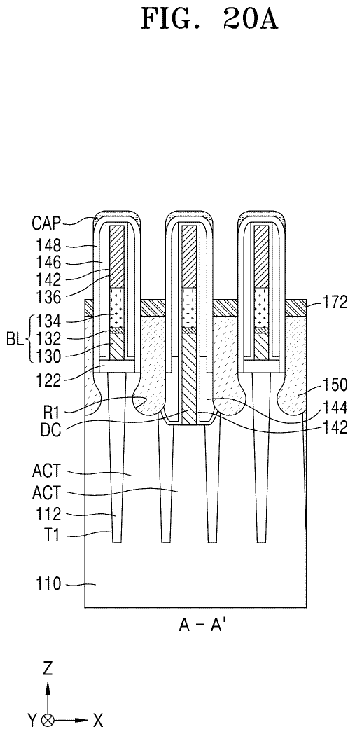

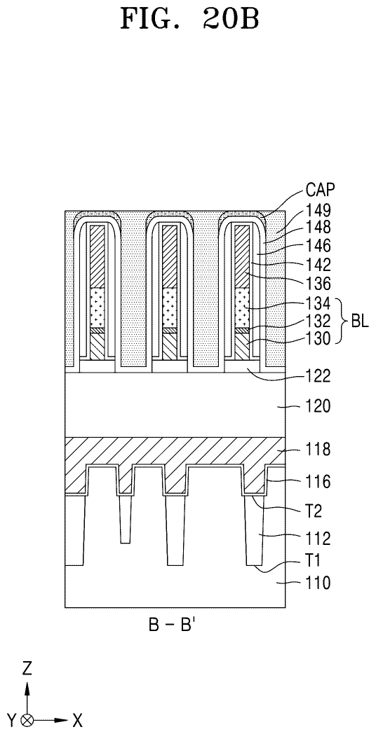

Referring to FIGS. 20A and 20B, the metal silicide film 172 may be formed on the plurality of contact plugs 150 of the resultant structure shown in FIGS. 19A and 19B. The contact plug 150 and the metal silicide film 172 may constitute at least a portion of the buried contact BC shown in FIG. 1.

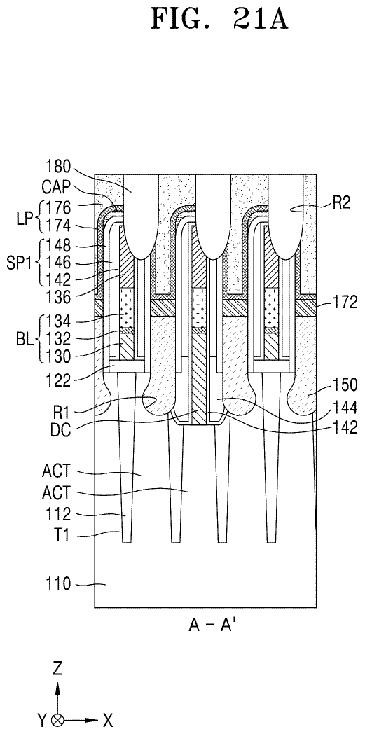

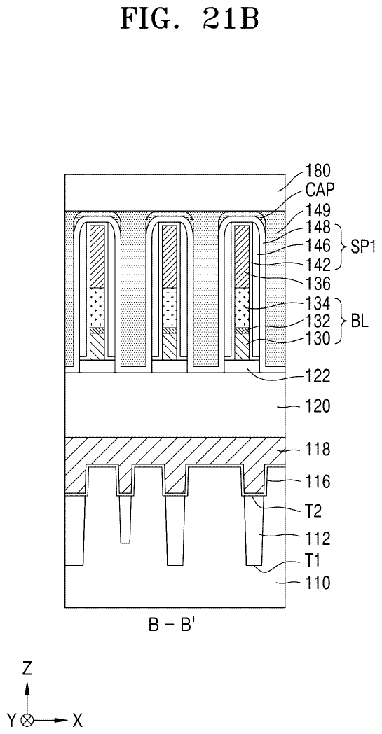

Referring to FIGS. 21A and 21B, the plurality of conductive landing pads LP may be formed on a resultant structure of FIGS. 20A and 20B. The plurality of conductive landing pads LP may fill the plurality of contact spaces CS on the metal silicide film 172 and extend onto the top of the insulation capping pattern 136 to vertically overlap some of the plurality of bit lines BL. The plurality of conductive landing pads LP may each include the conductive barrier film 174 and the conductive layer 176.

To form the plurality of conductive landing pads LP, the conductive barrier film 174 and the conductive layer 176 may be formed on the entire surface of a result structure having formed thereon the metal silicide film 172, a mask pattern (not shown) exposing a portion of the conductive layer 176 may be formed on the conductive layer 176, and an upper recess space R2 may be formed by etching the conductive layer 176, the conductive barrier film 174, and insulation layers around the conductive barrier film 174 by using the mask pattern as an etching mask. The mask pattern may include a silicon nitride film, but is not limited thereto.

The plurality of conductive landing pads LP may have a pattern shape like a plurality of islands. In the plurality of conductive landing pads LP, portions extending in the horizontal direction outside the contact spaces CS may constitute the plurality of conductive landing pads LP shown in FIG. 1.

The upper recess space R2 around the plurality of conductive landing pads LP may be filled with the insulation film 180 to electrically insulate the plurality of conductive landing pads LP from one another. Thereafter, a plurality of capacitor lower electrodes that may be electrically connected to a plurality of conductive landing pads LP may be formed on the insulation film 180.

According to embodiments, a doping process may be performed for the outer insulation spacers 148, thereby improving the etching resistance of the outer insulation spacers 148 and preventing the outer insulation spacers 148, the insulation capping patterns 136 surrounded by the outer insulation spacer 148, the inner insulation spacers 142, and the intermediate insulation spacers 146 from being consumed while the plurality of insulation fences 149 are being formed and while an etching process is being performed to form the plurality of recess spaces R1.

Also, the preliminary insulation capping film PCAP may be formed on the top of the outer insulation spacer 148, thereby preventing the insulation capping patterns 136 surrounded by the outer insulation spacer 148, the inner insulation spacers 142, and the intermediate insulation spacers 146 from being consumed while the plurality of insulation fences 149 are being formed and while an etching process is being performed to form the plurality of recess spaces R1. Therefore, a leakage current between the landing pad LP and the bit line BL that may occur when the insulation capping pattern 136, the inner insulation spacer 142, the intermediate insulation spacer 146, and the outer insulation spacer 148 are consumed may be prevented, and thus a method of manufacturing an integrated circuit device with improved reliability may be provided.

While the present inventive concept has been particularly shown and described with reference to embodiments thereof, it will be understood that various changes in form and details may be made therein without departing from the spirit and scope of the following claims.

What is claimed is:

1. An integrated circuit device, comprising:
a substrate having a plurality of active regions;
a bit line extending on the substrate in a horizontal direction parallel to an upper surface of the substrate;
a direct contact electrically connected to a first active region among the plurality of active regions and electrically connected to the bit line;
a contact plug electrically connected to a second active region among the plurality of active regions adjacent to the first active region; and
an outer insulation spacer between the bit line and the contact plug and overlapping the bit line in a vertical direction perpendicular to the upper surface of the substrate,
wherein the outer insulation spacer comprises a doped region doped with a metal element.

2. The integrated circuit device of claim 1, wherein an upper portion of the outer insulation spacer, facing away from the substrate, corresponds to the doped region.

3. The integrated circuit device of claim 1, further comprising a conductive landing pad that extends longitudinally in the vertical direction above the contact plug and is electrically connected to the contact plug,
wherein the conductive landing pad is spaced apart from the bit line with the outer insulation spacer therebetween.

4. The integrated circuit device of claim 1, wherein a cross-sectional thickness of the doped region of the outer insulation spacer is greater than a cross-sectional thickness of an undoped region of the outer insulation spacer.

5. The integrated circuit device of claim 1, wherein a cross-sectional thickness of an upper portion of the outer insulation spacer, facing away from the substrate, is greater than a cross-sectional thickness of a lower portion of the outer insulation spacer, facing towards the substrate.

6. The integrated circuit device of claim 1, wherein the outer insulation spacer comprises a silicon nitride film including the doped region, and
the integrated circuit device further comprises:
an inner insulation spacer between the outer insulation spacer and the bit line and comprising a silicon nitride film; and
an intermediate insulation spacer between the outer insulation spacer and the inner insulation spacer and comprising a silicon oxide film.

7. The integrated circuit device of claim 1, further comprising:
a conductive landing pad on the outer insulation spacer and contacting the contact plug; and
an insulation capping film between the outer insulation spacer and the conductive landing pad.

8. The integrated circuit device of claim 7, wherein the outer insulation spacer comprises a silicon nitride film including the doped region, and
the insulation capping film comprises an undoped silicon nitride film.

9. The integrated circuit device of claim 7, wherein a cross-sectional thickness of the insulation capping film decreases in a direction from a center of the insulation capping film toward an edge of the insulation capping film.

10. The integrated circuit device of claim 7, wherein sidewalls of the insulation capping film and sidewalls of the outer insulation spacer contact sidewalls of the conductive landing pad.

11. An integrated circuit device, comprising:
a substrate having a plurality of active regions;
a bit line extending on the substrate in a horizontal direction parallel to an upper surface of the substrate;
a direct contact electrically connected to a first active region of the plurality of active regions and electrically connected to the bit line;
a contact plug electrically connected to a second active region of the plurality of active regions, wherein the second active region is adjacent to the first active region in the horizontal direction;
a conductive landing pad extending on the contact plug in a vertical direction perpendicular to the upper surface of the substrate and electrically connected to the second active region through the contact plug;
an outer insulation spacer between the bit line and the contact plug, the outer insulation spacer overlapping the bit line in the vertical direction and comprising a doped region; and
an insulation capping film between the conductive landing pad and the outer insulation spacer.

12. The integrated circuit device of claim 11, wherein the doped region of the outer insulation spacer is doped with a metal.

13. The integrated circuit device of claim 11, wherein the insulation capping film is on the doped region of the outer insulation spacer.

14. The integrated circuit device of claim 11, wherein the insulation capping film is on the outer insulation spacer.

15. The integrated circuit device of claim 11, wherein a cross-sectional thickness of a portion of the outer insulation spacer that is in contact with the insulation capping film is greater than a cross-sectional thickness of a portion of the outer insulation spacer that is not in contact with the insulation capping film.

16. An integrated circuit device, comprising:
a substrate having a plurality of active regions;
a direct contact electrically connected to a first active region of the plurality of active regions;
a contact plug electrically connected to a second active region of the plurality of active regions adjacent to the first active region in a first horizontal direction parallel to an upper surface of the substrate;
a bit line extending longitudinally on the substrate in a second horizontal direction parallel to the upper surface of the substrate and intersecting with the first horizontal direction and electrically connected to the direct contact;
a conductive landing pad extending on the contact plug in a vertical direction perpendicular to the upper surface of the substrate and spaced apart from the bit line;
an insulation capping pattern between the bit line and the conductive landing pad on the bit line;
an inner insulation spacer on sidewalls of the direct contact and the bit line and on a top surface of the insulation capping pattern;
an outer insulation spacer between the conductive landing pad and the inner insulation spacer; and
an intermediate insulation spacer between the inner insulation spacer and the outer insulation spacer,
wherein an upper portion of the outer insulation spacer, facing away from the substrate, is doped with a metal element.

17. The integrated circuit device of claim 16, further comprising an insulation capping film between the conductive landing pad and the bit line,
wherein the insulation capping film is on the outer insulation spacer.

18. The integrated circuit device of claim 17, wherein a sidewall of the insulation capping film is coplanar with a sidewall of the outer insulation spacer.

19. The integrated circuit device of claim 16, wherein the outer insulation spacer comprises a portion that at least partially overlaps the insulation capping pattern, the inner insulation spacer, and the intermediate insulation spacer in the vertical direction.

20. The integrated circuit device of claim 16, wherein the upper portion of the outer insulation spacer overlaps the insulation capping pattern, the inner insulation spacer, and the intermediate insulation spacer in the vertical direction.
